(19) United States
(12) Patent Application Publication
(10) Pub. No.: US 2015/0380581 A1
(43) Pub. Date: Dec. 31, 2015

(54) PASSIVATION OF LIGHT-RECEIVING SURFACES OF SOLAR CELLS WITH CRYSTALLINE SILICON

(71) Applicants: Michael C. Johnson, Alameda, CA (US); Kieran Mark Tracy, San Jose, CA (US); Princess Carmi Tomada, Binan Laguna (PH); David D. Smith, Campbell, CA (US); Seung Bum Rim, Palo Alto, CA (US); Périne Jaffrennou, San Francisco, CA (US)

(72) Inventors: Michael C. Johnson, Alameda, CA (US); Kieran Mark Tracy, San Jose, CA (US); Princess Carmi Tomada, Binan Laguna (PH); David D. Smith, Campbell, CA (US); Seung Bum Rim, Palo Alto, CA (US); Périne Jaffrennou, San Francisco, CA (US)

(21) Appl. No.: 14/317,672

(22) Filed: Jun. 27, 2014

(51) Int. Cl. H01L 31/0368; H01L 31/028; H01L 31/18; H01L 31/077; H01L 31/0236; H01L 31/0216; H01L 31/0376

(52) U.S. Cl. CPC H01L 31/03685; H01L 31/02168; H01L 31/028; H01L 31/03682; H01L 31/03762; H01L 31/077; H01L 31/02366; H01L 31/182; H01L 31/1868; H01L 31/1872

(57) ABSTRACT

Methods of passivating light-receiving surfaces of solar cells with crystalline silicon, and the resulting solar cells, are described. In an example, a solar cell includes a silicon substrate having a light-receiving surface. An intrinsic silicon layer is disposed above the light-receiving surface of the silicon substrate. An N-type silicon layer is disposed on the intrinsic silicon layer. One or both of the intrinsic silicon layer and the N-type silicon layer is a micro- or poly-crystalline silicon layer. In another example, a solar cell includes a silicon substrate having a light-receiving surface. A passivating dielectric layer is disposed on the light-receiving surface of the silicon substrate. An N-type micro- or poly-crystalline silicon layer disposed on the passivating dielectric layer.

### TECHNICAL FIELD

Embodiments of the present disclosure are in the field of renewable energy and, in particular, methods of passivating light-receiving surfaces of solar cells with crystalline silicon, and the resulting solar cells.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present disclosure allow for increased solar cell manufacture efficiency by providing novel processes for fabricating solar cell structures. Some embodiments of the present disclosure allow for increased solar cell efficiency by providing novel solar cell structures.

### BRIEF DESCRIPTION OF THE DRAWINGS

FIGS. 1A-1E illustrate cross-sectional views of various stages in the fabrication of a solar cell, in accordance with an embodiment of the present disclosure, wherein:

FIG. 1A illustrates a starting substrate of a solar cell;

FIG. 1B illustrates the structure of FIG. 1A following formation of a passivating dielectric layer on a light-receiving surface of the substrate;

FIG. 1C illustrates the structure of FIG. 1B following formation of an intrinsic silicon layer on the passivating dielectric layer;

FIG. 1D illustrates the structure of FIG. 1C following formation of an N-type silicon layer on the intrinsic silicon layer; and

FIG. 1E illustrates the structure of FIG. 1D following formation of an anti-reflective coating (ARC) layer on the N-type silicon layer.

FIG. 2 is a flowchart listing operations in a method of fabricating a solar cell as corresponding to FIGS. 1A-1E, in accordance with an embodiment of the present disclosure.

FIG. 3 illustrates a cross-sectional view of a back-contact solar cell having emitter regions formed above a back surface of a substrate and having a first exemplary stack of layers on a light-receiving surface of the substrate, in accordance with an embodiment of the present disclosure.

FIG. 4 illustrates a cross-sectional view of a back-contact solar cell having emitter regions formed in a back surface of a substrate and having the first exemplary stack of layers on a light-receiving surface of the substrate, in accordance with an embodiment of the present disclosure.

FIG. 5 is an energy band diagram for the first exemplary stack of layers disposed on a light-receiving surface of the solar cells described in association with FIGS. 3 and 4, in accordance with an embodiment of the present disclosure.

FIG. 6A illustrates a cross-sectional view of a back-contact solar cell having emitter regions formed above a back surface of a substrate and having a second exemplary stack of layers on a light-receiving surface of the substrate, in accordance with an embodiment of the present disclosure.

FIG. 6B is an energy band diagram for the second exemplary stack of layers disposed on a light-receiving surface of the solar cell described in association with FIG. 6A, in accordance with an embodiment of the present disclosure.

FIG. 7A illustrates a cross-sectional view of a back-contact solar cell having emitter regions formed above a back surface of a substrate and having a third exemplary stack of layers on a light-receiving surface of the substrate, in accordance with an embodiment of the present disclosure.

FIG. 7B is an energy band diagram for the third exemplary stack of layers disposed on a light-receiving surface of the solar cell described in association with FIG. 7A, in accordance with an embodiment of the present disclosure.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” solar cell does not necessarily imply that this solar cell is the first solar cell in a sequence; instead the term “first” is used to differentiate this solar cell from another solar cell (e.g., a “second” solar cell).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Methods of passivating light-receiving surfaces of solar cells with crystalline silicon, and the resulting solar cells, are described herein. In the following description, numerous specific details are set forth, such as specific process flow operations, in order to provide a thorough understanding of embodiments of the present disclosure. It will be apparent to one skilled in the art that embodiments of the present disclosure may be practiced without these specific details. In other instances, well-known fabrication techniques, such as lithography and patterning techniques, are not described in detail in order to not unnecessarily obscure embodiments of the present disclosure. Furthermore, it is to be understood that the various embodiments shown in the figures are illustrative representations and are not necessarily drawn to scale.

Disclosed herein are solar cells. In one embodiment, a solar cell includes a silicon substrate having a light-receiving surface. An intrinsic silicon layer is disposed above the light-receiving surface of the silicon substrate. An N-type silicon layer is disposed on the intrinsic silicon layer. One or both of the intrinsic silicon layer and the N-type silicon layer is a micro- or poly-crystalline silicon layer.

In another embodiment, a solar cell includes a silicon substrate having a light-receiving surface. A passivating dielectric layer is disposed on the light-receiving surface of the silicon substrate. An N-type micro- or poly-crystalline silicon layer disposed on the passivating dielectric layer.

Also disclosed herein are methods of fabricating solar cells. In one embodiment, a method of fabricating a solar cell involves forming a passivating dielectric layer on a light-receiving surface of a silicon substrate. The method also involves forming an N-type micro- or poly-crystalline silicon layer above the passivating dielectric layer. The method also involves forming an anti-reflective coating (ARC) layer on the N-type micro- or poly-crystalline silicon layer.

One or more embodiments described herein are directed to approaches for achieving improved front surface field (FSF) performance for solar cells. In one embodiment, improved FSF performance is achieved using a crystalline silicon (Si) interlayer to provide improved efficiency and reliability.

To provide context, light induced degradation (LID) and/or ultra-violet (UV) degradation pose long standing issues for the long term stability of solar cell performance. High efficiency solar cells are especially subject to such degradation modes due to their increased sensitivity of the front surface passivation. Efforts have been exerted in improving the stability of such solar cells without compromising performance in the form of decreased passivation or solar spectrum absorption (e.g., Jsc loss). Performance stability may be critical for performance guarantees and for product quality differentiation. More particularly, front surface passivation can be critical for performance of high efficiency solar cells. Typically, front surface passivation is performed using a diffusion process followed by a high temperature oxidation and, finally, capping with an antireflection coating (ARC) using plasma-enhanced chemical vapor deposition (PECVD). Silicon nitride (SiN or SiN:H) is commonly used as an ARC due to its optical properties and also for its excellent passivation qualities. A silicon nitride layer may be used to provide H+ to a crystalline silicon/thermal oxide (c-Si/TOX) interface. Unfortunately, the interface can be degraded by long term exposure to UV light via hot electron injection across the interface which breaks existing Si—H bonds. The hot electron can be trapped in the subsequent layers and be re-excited to bounce back and forth across the interface, which is a process known as interface wear.

Addressing one or more of the above issues, in accordance with one or more embodiments described herein, efficiency and reliability of a solar cell are improved by inserting a crystallized silicon (Si) interlayer between a passivating oxide layer and an ARC layer, such as a SiN or SiN:H layer. In one embodiment, by inserting a crystallized or partially crystallized Si interlayer between the thermal oxide and SiN or SiN:H ARC layer, passivation and stability of the c-Si/TOX interface are improved. Additionally, an increase in Jsc may be achieved for the solar cell by using a more transparent interlayer. Such an interlayer may be deposited by a number of suitable methods. In one embodiment, direct deposition of a micro- or poly-crystalline N-type silicon (pc-Si:n) layer or polycrystalline Si:n layer is performed. In another embodiment, post-processing is performed to first deposit an amorphous N-type silicon (aSi:n) layer and then using an anneal process to crystallize the deposited layer. Post-processing may be performed with or without the ARC layer being present.

Not to be bound by theory, in an embodiment, improved stability achieved by direct deposition or phase conversion to a more crystallized phase improves the stress state of the N-type silicon interlayer which counter balances the compressive nature of the underlying thermal oxide. The result is a more energetically favorable Si—O bonding scenario. Additionally, converting to a crystallized state may reduce the total number of O—H bonds at the surface of the underlying thermal oxide, reducing the amount of trap states for hot electron trapping and resulting in decreased interface wear.

More generally, in accordance with one or more embodiments, an intrinsic microcrystalline or amorphous silicon:N-type micro- or poly-crystalline silicon (represented as i:n) structure is fabricated with or without a thin oxide for improved passivation. In another embodiment, the N-type micro- or poly-crystalline silicon layer can be used alone, so long as the thin oxide is of sufficiently high quality to maintain good passivation. In cases where an intrinsic micro- or poly-crystalline or amorphous silicon is implemented, the material provides an additional passivation protection for cases suffering from a defective oxide. In some embodiments, inclusion of a phosphorous-doped micro- or poly-crystalline silicon layer in addition to the intrinsic layer improves stability against UV degradation. The phosphorous-doped layer can be implemented to enable band-bending which aids in shielding the interface by repelling the minority carriers reducing the amount of recombination.

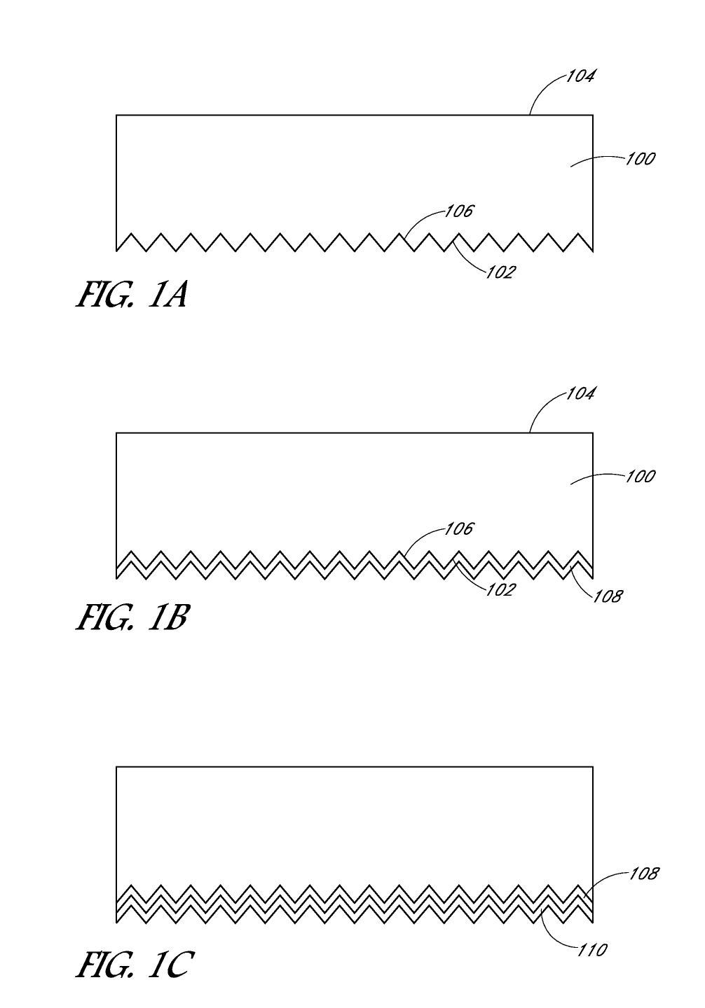

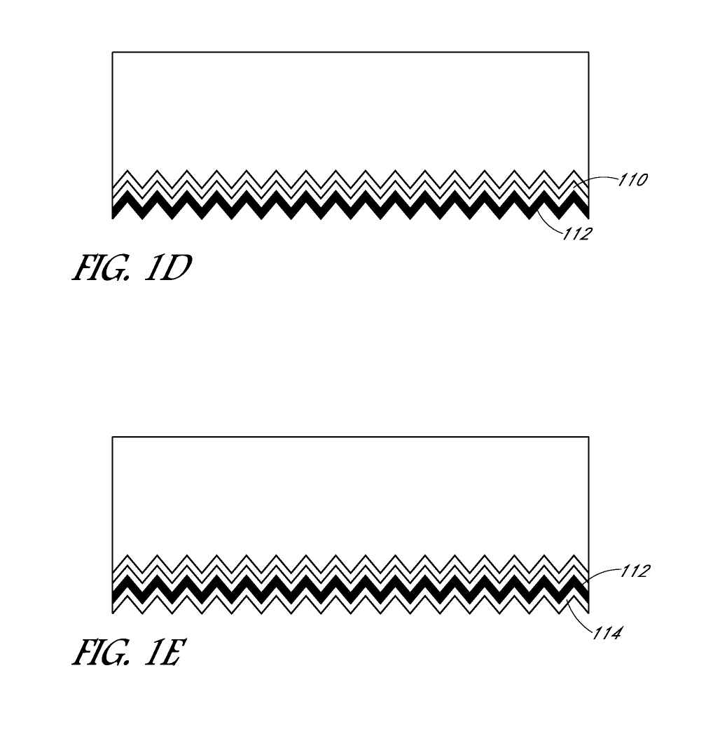

FIGS. 1A-1E illustrate cross-sectional views of various stages in the fabrication of a solar cell, in accordance with an embodiment of the present disclosure. FIG. 2 is a flowchart listing operations in a method of fabricating a solar cell as corresponding to FIGS. 1A-1E, in accordance with an embodiment of the present disclosure.

FIG. 1A illustrates a starting substrate of a solar cell. Referring to FIG. 1A, substrate 100 has a light-receiving surface 102 and a back surface 104. In an embodiment, the substrate 100 is a monocrystalline silicon substrate, such as a bulk single crystalline N-type doped silicon substrate. It is to be appreciated, however, that substrate 100 may be a layer, such as a multi-crystalline silicon layer, disposed on a global solar cell substrate. In an embodiment, the light-receiving surface 102 has a texturized topography 106. In one such embodiment, a hydroxide-based wet etchant is employed to texturize the front surface of the substrate 100. It is to be appreciated that a texturized surface may be one which has a regular or an irregular shaped surface for scattering incoming light, decreasing the amount of light reflected off of the light-receiving surfaces of the solar cell.

FIG. 1B illustrates the structure of FIG. 1A following formation of a passivating dielectric layer on a light-receiving surface of the substrate. Referring to FIG. 1B and corresponding operation 202 of flowchart 200, a passivating dielectric layer 108 is formed on the light-receiving surface 102 of substrate 100. In one embodiment, the light-receiving surface 102 has a texturized topography 106, and the passivating dielectric layer 108 is conformal with the texturized topography 106, as is depicted in FIG. 1B.

In an embodiment, the passivating dielectric layer 108 is a layer of silicon dioxide (SiO₂). In one such embodiment, the layer of silicon dioxide (SiO₂) has a thickness approximately in the range of 10-200 Angstroms. In one embodiment, the passivating dielectric layer 108 is hydrophilic. In an embodiment, the passivating dielectric layer 108 is formed by a technique such as, but not limited to, chemical oxidation of a portion of the light-receiving surface of the silicon substrate, plasma-enhanced chemical vapor deposition (PECVD) of silicon dioxide (SiO₂), thermal oxidation of a portion of the light-receiving surface of the silicon substrate, atomic layer deposition (ALD) of SiO₂ or AlOx, or exposure of the light-receiving surface of the silicon substrate to ultra-violet (UV) radiation in an O₂ or O₃ environment.

FIG. 1C illustrates the structure of FIG. 1B following formation of an intrinsic silicon layer on the passivating dielectric layer. Referring to FIG. 1C, an intrinsic silicon layer 110 is formed on the passivating dielectric layer 108. In one embodiment, as is depicted in FIG. 1C, the intrinsic silicon layer 110 is conformal with the texturized topography 106.

In an embodiment, the intrinsic silicon layer 110 is an intrinsic micro- or poly-crystalline silicon layer. In one such embodiment, the intrinsic micro- or poly-crystalline silicon layer has a thickness approximately in the range of 1-5 nanometers. In one embodiment, the intrinsic micro- or poly-crystalline silicon layer has a crystalline fraction approximately in the range of 0.1-0.9 (i.e., 10-90%), with the balance being amorphous. In one embodiment, the intrinsic micro- or poly-crystalline silicon layer includes small grains having a micro or nano-diameter. The small grains may be embedded in a generally amorphous silicon matrix and have essentially no long range order.

In an embodiment, the intrinsic micro- or poly-crystalline silicon layer is formed by depositing an intrinsic amorphous silicon layer and, subsequently, phase converting the intrinsic amorphous silicon layer to the intrinsic micro- or poly-crystalline silicon layer. In one such embodiment, the intrinsic amorphous silicon layer is formed by a deposition process such as, but not limited to, plasma-enhanced chemical vapor deposition (PECVD), low pressure chemical vapor deposition (LPCVD), or sputtering (physical vapor deposition, PVD). In one embodiment, the phase conversion is achieved using a technique such as, but not limited to, heating in a furnace, rapid thermal processing (RTP), laser annealing, or forming gas annealing (FGA). In another embodiment, the intrinsic micro- or poly-crystalline silicon layer is formed by depositing the intrinsic micro- or poly-crystalline silicon layer. In one such embodiment, the intrinsic micro- or poly-crystalline silicon layer is deposited using PECVD.

In another embodiment, the intrinsic silicon layer 110 is an intrinsic amorphous silicon layer. In one such embodiment, the intrinsic amorphous silicon layer has a thickness approximately in the range of 1-5 nanometers. In one embodiment, forming the intrinsic amorphous silicon layer on the passivating dielectric layer 108 is performed at a temperature less than approximately 400 degrees Celsius. In an embodiment, the intrinsic amorphous silicon layer is formed using plasma enhanced chemical vapor deposition (PECVD), represented by a-Si:H, which includes Si—H covalent bonds throughout the layer.

FIG. 1D illustrates the structure of FIG. 1C following formation of an N-type silicon layer on the intrinsic silicon layer. Referring to FIG. 1D and corresponding operation 204 of flowchart 200, an N-type silicon layer 112 is formed on the intrinsic silicon layer 110. In one embodiment, as is depicted in FIG. 1D, the N-type silicon layer 112 is conformal with the texturized topography 106.

In an embodiment, the N-type silicon layer 112 is an N-type micro- or poly-crystalline silicon layer. In one such embodiment, the intrinsic micro- or poly-crystalline silicon layer has a thickness approximately in the range of 1-20 nanometers. In one embodiment, the N-type micro- or poly-crystalline silicon layer has a crystalline fraction approximately in the range of 0.1-0.9 (i.e., 10-90%), with the balance being amorphous. In an embodiment, a concentration of N-type dopants (e.g., phosphorous) in the N-type micro- or poly-crystalline silicon layer is approximately in the range of 1E17-1E20 atoms/cm³. In one embodiment, the N-type micro- or poly-crystalline silicon layer includes small grains having a micro- or nano-diameter. The small grains may be embedded in a generally amorphous silicon matrix and have essentially no long range order. In an embodiment, the N-type dopants are included in the amorphous portion, in the crystalline portion, or both.

In an embodiment, the N-type micro- or poly-crystalline silicon layer is formed by depositing an N-type amorphous silicon layer and, subsequently, phase converting the N-type amorphous silicon layer to the N-type micro- or poly-crystalline silicon layer. In one such embodiment, the N-type amorphous silicon layer is formed by a deposition process such as, but not limited to, plasma-enhanced chemical vapor deposition (PECVD), low pressure chemical vapor deposition (LPCVD), or sputtering (physical vapor deposition, PVD). In one embodiment, the phase conversion is achieved using a technique such as, but not limited to, heating in a furnace, rapid thermal processing (RTP), laser annealing, or forming gas annealing (FGA). In another embodiment, the N-type micro- or poly-crystalline silicon layer is formed by depositing the N-type micro- or poly-crystalline silicon layer. In one such embodiment, the N-type micro- or poly-crystalline silicon layer is deposited using PECVD.

In another embodiment, the N-type silicon layer 112 is an N-type amorphous silicon layer. In one embodiment, forming the N-type amorphous silicon layer on the intrinsic silicon layer 110 is performed at a temperature less than approximately 400 degrees Celsius. In an embodiment, the N-type amorphous silicon layer is formed using plasma enhanced chemical vapor deposition (PECVD), represented by phosphorous-doped a-Si:H, which includes Si—H covalent bonds throughout the layer.

In either case, in an embodiment, the micro- or poly-crystalline or amorphous N-type silicon layer 112 includes an impurity such as phosphorous dopants. In one such embodiment, the phosphorous dopants are incorporated either during film deposition or in a post implantation operation.

With reference again to FIG. 1D, in a first embodiment, the intrinsic silicon layer 110 is an amorphous intrinsic silicon layer, and the N-type silicon layer 112 is a micro- or poly-crystalline N-type silicon layer. In a second embodiment, the intrinsic silicon layer 110 is a micro- or poly-crystalline intrinsic silicon layer, and the N-type silicon layer 112 is an amorphous N-type silicon layer. In a third embodiment, the intrinsic silicon layer 110 is a micro- or poly-crystalline intrinsic silicon layer, and the N-type silicon layer 112 is a micro- or poly-crystalline N-type silicon layer.

FIG. 1E illustrates the structure of FIG. 1D following formation of an anti-reflective coating (ARC) layer on the N-type silicon layer. Referring to FIG. 1E and corresponding operation 206 of flowchart 200, an anti-reflective coating (ARC) layer 114 is formed on the N-type silicon layer 112. In one embodiment, as is depicted in FIG. 1E, the ARC layer 114 is conformal with the texturized topography 106.

In an embodiment, the ARC layer 114 is a non-conductive ARC layer. In one such embodiment, the non-conductive ARC layer includes silicon nitride. In a particular such embodiment, the silicon nitride is formed at a temperature less than approximately 400 degrees Celsius. In another embodiment, the ARC layer 114 is a conductive ARC layer. In one such embodiment, the conductive ARC layer includes a layer of indium tin oxide (ITO).

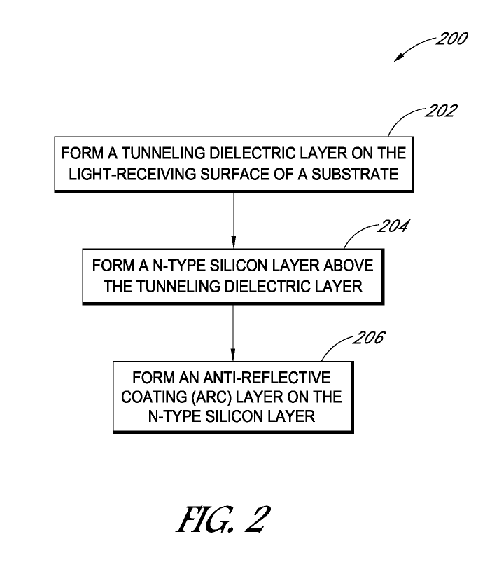

FIG. 3 illustrates a cross-sectional view of a back-contact solar cell having emitter regions formed above a back surface of a substrate and having a first exemplary stack of layers on a light-receiving surface of the substrate, in accordance with an embodiment of the present disclosure.

Referring to FIG. 3, a solar cell includes a silicon substrate 100 having a light-receiving surface 102. A passivating dielectric layer 108 is disposed on the light-receiving surface of the silicon substrate 100. An intrinsic silicon layer 110 is disposed on the passivating dielectric layer 108. An N-type silicon layer 112 is disposed on the intrinsic silicon layer 110. An anti-reflective coating (ARC) layer 114 is disposed on the N-type silicon layer 112. As such, the stack of layers on the light-receiving surface of the solar cell of FIG. 3 is the same as that described in association with FIG. 1A-1E.

With reference again to FIG. 3, in a first embodiment, the intrinsic silicon layer 110 is an amorphous intrinsic silicon layer, and the N-type silicon layer 112 is a micro- or poly-crystalline N-type silicon layer. In a second embodiment, the intrinsic silicon layer 110 is a micro- or poly-crystalline intrinsic silicon layer, and the N-type silicon layer 112 is an amorphous N-type silicon layer. In a third embodiment, the intrinsic silicon layer 110 is a micro- or poly-crystalline intrinsic silicon layer, and the N-type silicon layer 112 is a micro- or poly-crystalline N-type silicon layer.

Referring again to FIG. 3, on the back surface of the substrate 100, alternating P-type 120 and N-type 122 emitter regions are formed. In one such embodiment, trenches 121 are disposed between the alternating P-type 120 and N-type 122 emitter regions. More particularly, in an embodiment, first polycrystalline silicon emitter regions 122 are formed on a first portion of a thin dielectric layer 124 and are doped with an N-type impurity. Second polycrystalline silicon emitter regions 120 are formed on a second portion of the thin dielectric layer 124 and are doped with a P-type impurity. In an embodiment the tunnel dielectric 124 is a silicon oxide layer having a thickness of approximately 2 nanometers or less.

Referring again to FIG. 3, conductive contact structures 128/130 are fabricated by first depositing and patterning an insulating layer 126 to have openings and then forming one or more conductive layers in the openings. In an embodiment, the conductive contact structures 128/130 include metal and are formed by a deposition, lithographic, and etch approach or, alternatively, a printing or plating process or, alternatively, a foil adhesion process.

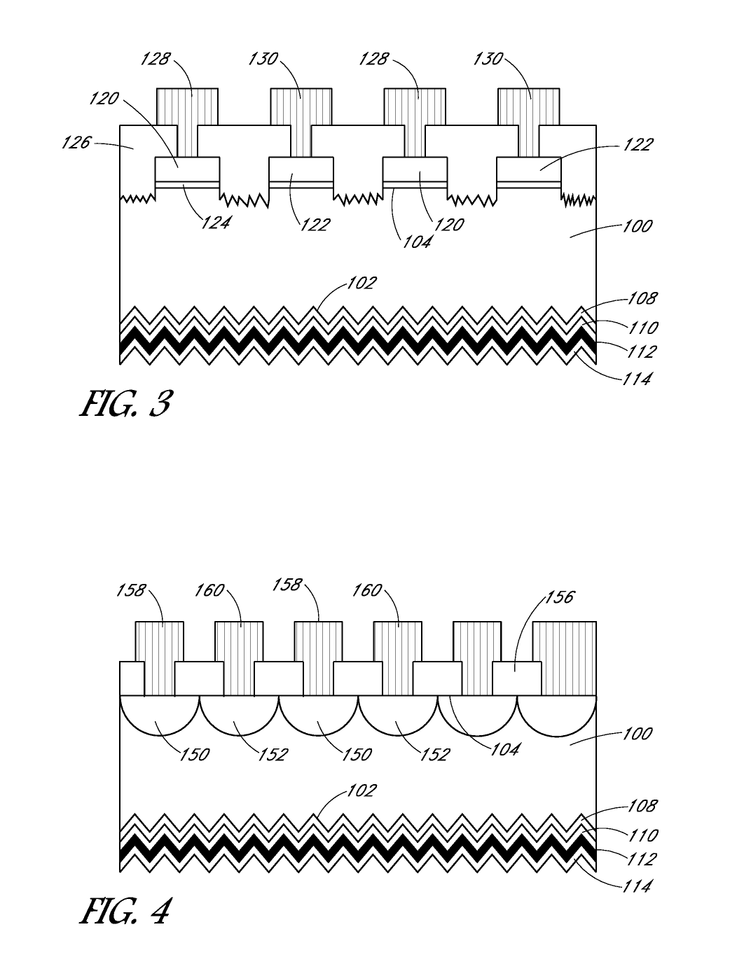

FIG. 4 illustrates a cross-sectional view of a back-contact solar cell having emitter regions formed in a back surface of a substrate and having the first exemplary stack of layers on a light-receiving surface of the substrate, in accordance with an embodiment of the present disclosure.

Referring to FIG. 4, a solar cell includes a silicon substrate 100 having a light-receiving surface 102. A passivating dielectric layer 108 is disposed on the light-receiving surface of the silicon substrate 100. An intrinsic silicon layer 110 is disposed on the passivating dielectric layer 108. An N-type silicon layer 112 is disposed on the intrinsic silicon layer 110. An anti-reflective coating (ARC) layer 114 is disposed on the N-type silicon layer 112. As such, the stack of layers on the light-receiving surface of the solar cell of FIG. 4 is the same as that described in association with FIG. 1A-1E.

With reference again to FIG. 4, in a first embodiment, the intrinsic silicon layer 110 is an amorphous intrinsic silicon layer, and the N-type silicon layer 112 is a micro- or poly-crystalline N-type silicon layer. In a second embodiment, the intrinsic silicon layer 110 is a micro- or poly-crystalline intrinsic silicon layer, and the N-type silicon layer 112 is an amorphous N-type silicon layer. In a third embodiment, the intrinsic silicon layer 110 is a micro- or poly-crystalline intrinsic silicon layer, and the N-type silicon layer 112 is a micro- or poly-crystalline N-type silicon layer.

Referring again to FIG. 4, within the back surface of the substrate 100, alternating P-type 150 and N-type 152 emitter regions are formed. More particularly, in an embodiment, first emitter regions 152 are formed within a first portion of substrate 100 and are doped with an N-type impurity. Second emitter regions 150 are formed within a second portion of substrate 100 and are doped with a P-type impurity. Referring again to FIG. 4, conductive contact structures 158/160 are fabricated by first depositing and patterning an insulating layer 156 to have openings and then forming one or more conductive layers in the openings. In an embodiment, the conductive contact structures 158/160 include metal and are formed by a deposition, lithographic, and etch approach or, alternatively, a printing or plating process or, alternatively, a foil adhesion process.

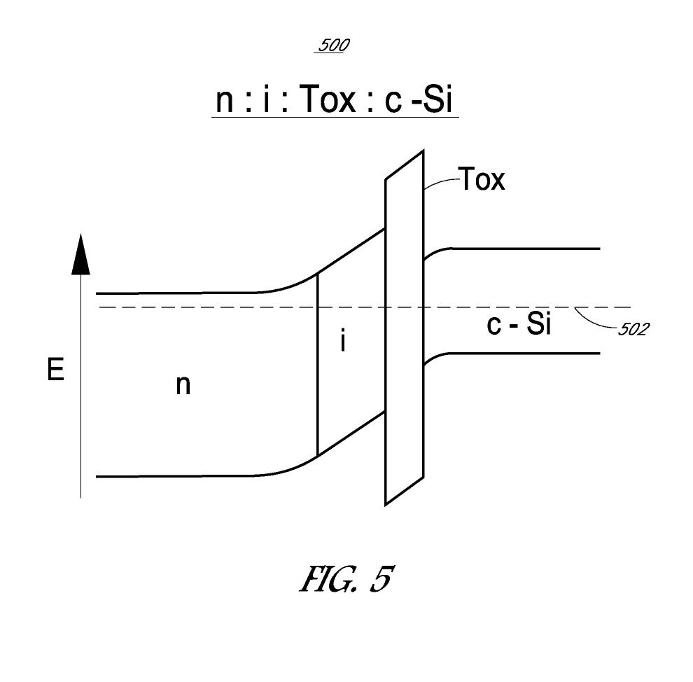

FIG. 5 is an energy band diagram 500 for the first exemplary stack of layers disposed on a light-receiving surface of the solar cells described in association with FIGS. 3 and 4, in accordance with an embodiment of the present disclosure. Referring to the energy band diagram 500, a band structure is provided for a material stack including N-type doped silicon (n), intrinsic silicon (i), a thin oxide layer (Tox), and the crystalline silicon substrate (c-Si). The Fermi level is shown at 502 and reveals good passivation of the light-receiving surface of a substrate having this material stack.

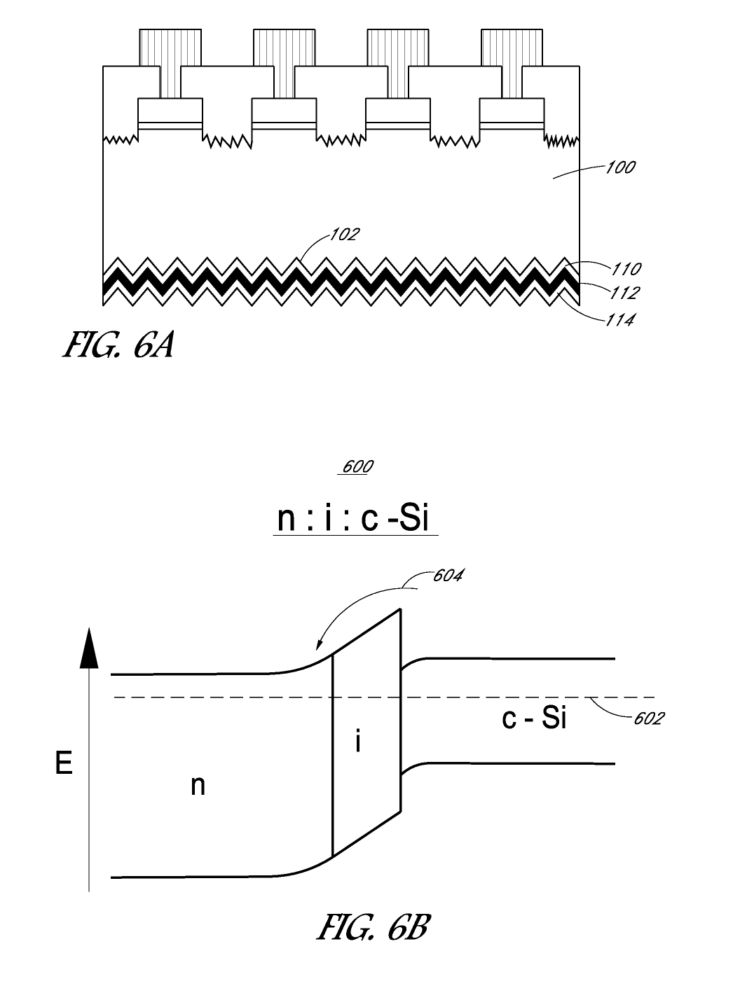

FIG. 6A illustrates a cross-sectional view of a back-contact solar cell having emitter regions formed above a back surface of a substrate and having a second exemplary stack of layers on a light-receiving surface of the substrate, in accordance with an embodiment of the present disclosure.

Referring to FIG. 6A, a solar cell includes a silicon substrate 100 having a light-receiving surface 102. An intrinsic silicon layer 110 is disposed on the light-receiving surface 102 of the silicon substrate 100 (in this case, the growth may be epitaxial). An N-type silicon layer 112 is disposed on the intrinsic silicon layer 110. An anti-reflective coating (ARC) layer 114 is disposed on the N-type silicon layer 112. As such, the stack of layers on the light-receiving surface of the solar cell of FIG. 6A does not include the passivating dielectric layer 108 described in association with FIG. 3. Other features described in association with FIG. 3, however, are similar. Furthermore, it is to be appreciated that emitter region may be formed within the substrate, as is described in association with FIG. 4.

With reference again to FIG. 6A, in a first embodiment, the intrinsic silicon layer 110 is an amorphous intrinsic silicon layer, and the N-type silicon layer 112 is a micro- or poly-crystalline N-type silicon layer. In a second embodiment, the intrinsic silicon layer 110 is a micro- or poly-crystalline intrinsic silicon layer, and the N-type silicon layer 112 is an amorphous N-type silicon layer. In a third embodiment, the intrinsic silicon layer 110 is a micro- or poly-crystalline intrinsic silicon layer, and the N-type silicon layer 112 is a micro- or poly-crystalline N-type silicon layer.

FIG. 6B is an energy band diagram 600 for the second exemplary stack of layers disposed on a light-receiving surface of the solar cell described in association with FIG. 6A, in accordance with an embodiment of the present disclosure. Referring to the energy band diagram 600, a band structure is provided for a material stack including N-type doped silicon (n), intrinsic silicon (i), and a crystalline silicon substrate (c-Si). The Fermi level is shown at 602 and reveals good passivation of the light-receiving surface of a substrate having this material stack even though an oxide layer is not in place to block pathway 604.

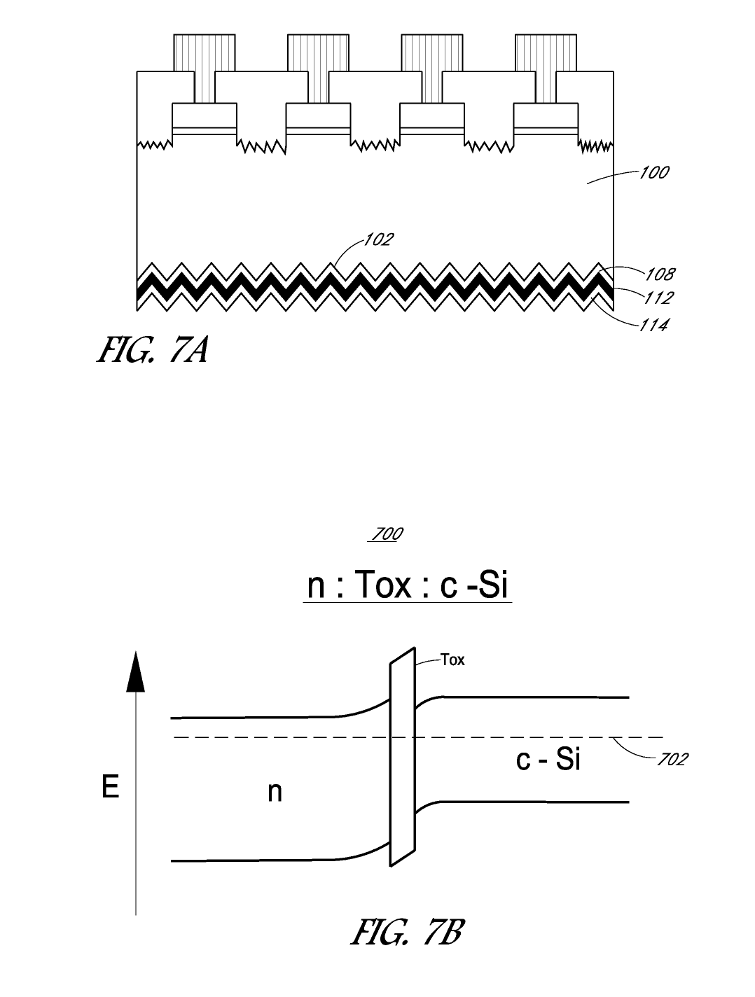

FIG. 7A illustrates a cross-sectional view of a back-contact solar cell having emitter regions formed above a back surface of a substrate and having a third exemplary stack of layers on a light-receiving surface of the substrate, in accordance with an embodiment of the present disclosure.

Referring to FIG. 7A, a solar cell includes a silicon substrate 100 having a light-receiving surface 102. A passivating dielectric layer 108 is disposed on the light-receiving surface 102 of the silicon substrate 100. A micro- or poly-crystalline N-type silicon layer 112 is disposed on the passivating dielectric layer 108. An anti-reflective coating (ARC) layer 114 is disposed on the micro- or poly-crystalline N-type silicon layer 112. As such, the stack of layers on the light-receiving surface of the solar cell of FIG. 7A does not include the micro- or poly-crystalline or amorphous intrinsic silicon layer 110 described in association with FIG. 3. Other features described in association with FIG. 3, however, are similar. Furthermore, it is to be appreciated that emitter region may be formed within the substrate, as is described in association with FIG. 4.

FIG. 7B is an energy band diagram 700 for the third exemplary stack of layers disposed on a light-receiving surface of the solar cell described in association with FIG. 7A, in accordance with an embodiment of the present disclosure. Referring to the energy band diagram 700, a band structure is provided for a material stack including micro- or poly-crystalline N-type doped silicon (n), a thin oxide layer (Tox), and the crystalline silicon substrate (c-Si). The Fermi level is shown at 702 and reveals good passivation of the light-receiving surface of a substrate having this material stack.

Overall, although certain materials are described specifically above, some materials may be readily substituted with others with other such embodiments remaining within the spirit and scope of embodiments of the present disclosure. For example, in an embodiment, a different material substrate, such as a group III-V material or multicrystalline substrate, can be used instead of a silicon substrate. In addition, it is to be understood that the substrate can be either n+ or p+ type material. Furthermore, it is to be understood that, where N+ and P+ type doping is described specifically for emitter regions on a back surface of a solar cell, other embodiments contemplated include the opposite conductivity type, e.g., P+ and N+ type doping, respectively. This may also be applied to front contact cells and bi-facial cell architectures.

Thus, methods of passivating light-receiving surfaces of solar cells with crystalline silicon, and the resulting solar cells, have been disclosed.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

1. A solar cell, comprising:
a silicon substrate having a light-receiving surface;
an intrinsic silicon layer disposed above the light-receiving surface of the silicon substrate; and
an N-type silicon layer disposed on the intrinsic silicon layer, wherein one or both of the intrinsic silicon layer and the N-type silicon layer is a micro- or poly-crystalline silicon layer.

2. The solar cell of claim 1, wherein the N-type silicon layer is an N-type micro- or poly-crystalline silicon layer having a crystalline fraction approximately in the range of 0.1-0.9, with the balance being amorphous.

3. The solar cell of claim 2, wherein a concentration of N-type dopants in the N-type micro- or poly-crystalline silicon layer is approximately in the range of 1E17-1E20 atoms/cm³.

4. The solar cell of claim 1, further comprising:
a passivating dielectric layer disposed on the light-receiving surface of the silicon substrate, wherein the intrinsic silicon layer is disposed on the passivating dielectric layer.

5. The solar cell of claim 4, wherein the passivating dielectric layer is a layer of silicon dioxide (SiO₂) having a thickness approximately in the range of 10-200 Angstroms.

6. The solar cell of claim 1, further comprising:
an anti-reflective coating (ARC) layer disposed on the N-type silicon layer.

7. The solar cell of claim 1, wherein the light-receiving surface has a texturized topography, and wherein both the intrinsic silicon layer and the N-type silicon layer are conformal with the texturized topography of the light-receiving surface.

8. The solar cell of claim 1, wherein the substrate further comprises a back surface opposite the light-receiving surface, the solar cell further comprising:
a plurality of alternating N-type and P-type semiconductor regions at or above the back surface of the substrate; and
a conductive contact structure electrically connected to the plurality of alternating N-type and P-type semiconductor regions.

9. A solar cell, comprising:
a silicon substrate having a light-receiving surface;
a passivating dielectric layer disposed on the light-receiving surface of the silicon substrate; and
an N-type micro- or poly-crystalline silicon layer disposed on the passivating dielectric layer.

10. The solar cell of claim 9, wherein the N-type micro- or poly-crystalline silicon layer has a crystalline fraction approximately in the range of 0.1-0.9, with the balance being amorphous.

11. The solar cell of claim 10, wherein a concentration of N-type dopants in the N-type micro- or poly-crystalline silicon layer is approximately in the range of 1e17-1e20 atoms/cm³.

12. The solar cell of claim 9, further comprising:
an anti-reflective coating (ARC) layer disposed on the N-type micro- or poly-crystalline silicon layer.

13. The solar cell of claim 9, wherein the passivating dielectric layer is a layer of silicon dioxide (SiO₂) having a thickness approximately in the range of 10-200 Angstroms.

14. The solar cell of claim 9, wherein the light-receiving surface of the substrate has a texturized topography, and wherein the N-type micro- or poly-crystalline silicon layer is conformal with the texturized topography of the light-receiving surface.

15. The solar cell of claim 9, wherein the substrate further comprises a back surface opposite the light-receiving surface, the solar cell further comprising:
a plurality of alternating N-type and P-type semiconductor regions at or above the back surface of the substrate; and
a conductive contact structure electrically connected to the plurality of alternating N-type and P-type semiconductor regions.

16. A method of fabricating a solar cell, the method comprising:
forming a passivating dielectric layer on a light-receiving surface of a silicon substrate;
forming an N-type micro- or poly-crystalline silicon layer above the passivating dielectric layer; and
forming an anti-reflective coating (ARC) layer on the N-type micro- or poly-crystalline silicon layer.

17. The method of claim 16, wherein forming an N-type micro- or poly-crystalline silicon layer comprises depositing an N-type amorphous silicon layer and, subsequently, phase converting the N-type amorphous silicon layer to the N-type micro- or poly-crystalline silicon layer.

18. The method of claim 16, wherein forming an N-type micro- or poly-crystalline silicon layer comprises depositing the N-type micro- or poly-crystalline silicon layer.

19. The method of claim 16, further comprising:
forming an intrinsic micro- or poly-crystalline or amorphous silicon layer on the passivating dielectric layer, wherein forming the N-type micro- or poly-crystalline silicon layer comprises forming on the intrinsic micro- or poly-crystalline or amorphous silicon layer.

20. The method of claim 16, wherein forming the passivating dielectric layer comprises using a technique selected from the group consisting of chemical oxidation of a portion of the light-receiving surface of the silicon substrate, plasma-enhanced chemical vapor deposition (PECVD) of silicon dioxide (SiO₂), atomic layer deposition (ALD) of SiO₂ or AlOx, thermal oxidation of a portion of the light-receiving surface of the silicon substrate, and exposure of the light-receiving surface of the silicon substrate to ultra-violet (UV) radiation in an O₂ or O₃ environment.

21. (canceled)
